(19) United States
(12) Patent Application Publication
(10) Pub. No.: US 2025/0270691 A1
(43) Pub. Date: Aug. 28, 2025

(54) SUBSTRATE PROCESSING APPARATUS

(71) Applicant: Tokyo Electron Limited, Tokyo (JP)

(72) Inventor: Kohei SUGAWARA, Oshu City (JP)

(21) Appl. No.: 19/055,583

(22) Filed: Feb. 18, 2025

(30) Foreign Application Priority Data
Feb. 22, 2024 (JP) 2024-025088

(51) Int. Cl. C23C 16/44; C23C 16/455

(52) U.S. Cl. CPC C23C 16/4412; C23C 16/4409; C23C 16/45561

(57) ABSTRACT

A substrate processing apparatus includes a reaction tube, a vacuum pipe integrally formed with the reaction tube, a housing configured to accommodate the reaction tube and the vacuum pipe therein, an exhaust pipe provided below the housing, and a fixing member configured to fix the exhaust pipe to the housing. The housing has a bottom portion configured to support the reaction tube, the bottom portion has an opening with an opening diameter larger than an outer diameter of the vacuum pipe, the vacuum pipe has a lower end inserted through the opening, and the exhaust pipe is fixed to the housing in a state in which an interior thereof communicates with an interior of the vacuum pipe.

### CROSS-REFERENCE TO RELATED APPLICATION

This application is based upon and claims the benefit of priority from Japanese Patent Application No. 2024-025088, filed on Feb. 22, 2024, the entire contents of which are incorporated herein by reference.

### TECHNICAL FIELD

The present disclosure relates to a substrate processing apparatus.

### BACKGROUND

In a batch-type vacuum processing apparatus, a technique is known in which a bellows body that is stretchable and bendable is provided at a connection portion between an exhaust port of a reaction tube and a vacuum pipe (see, for example, Patent Document 1).

### PRIOR ART DOCUMENT

### Patent Document

Patent Document 1: Japanese Patent Laid-Open Publication No. 2012-104755

### SUMMARY

According to one embodiment of the present disclosure, a substrate processing apparatus includes a reaction tube, a vacuum pipe integrally formed with the reaction tube, a housing configured to accommodate the reaction tube and the vacuum pipe therein, an exhaust pipe provided below the housing, and a fixing member configured to fix the exhaust pipe to the housing. The housing has a bottom portion configured to support the reaction tube, the bottom portion has an opening with an opening diameter larger than an outer diameter of the vacuum pipe, the vacuum pipe has a lower end inserted through the opening, and the exhaust pipe is fixed to the housing in a state in which an interior thereof communicates with an interior of the vacuum pipe.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view showing a substrate processing apparatus according to an embodiment.

FIG. 2 is a perspective view showing the substrate processing apparatus according to the embodiment.

FIG. 3 is a vertical cross-sectional view showing the substrate processing apparatus according to the embodiment.

FIG. 4 is a horizontal cross-sectional view showing the substrate processing apparatus according to the embodiment.

FIG. 5 is a horizontal cross-sectional view showing the substrate processing apparatus according to the embodiment.

FIG. 6 is a cross-sectional view showing a pipe connection structure.

FIG. 7 is an enlarged view of area A in FIG. 6.

FIG. 8 is a cross-sectional view showing a pipe connection method.

FIG. 9 is a cross-sectional view showing the pipe connection method.

FIG. 10 is a cross-sectional view showing the pipe connection method.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. Throughout all the accompanying drawings, the same or corresponding members or components will be denoted by the same or corresponding reference numerals, and redundant descriptions thereof will be omitted.

### Substrate Processing Apparatus

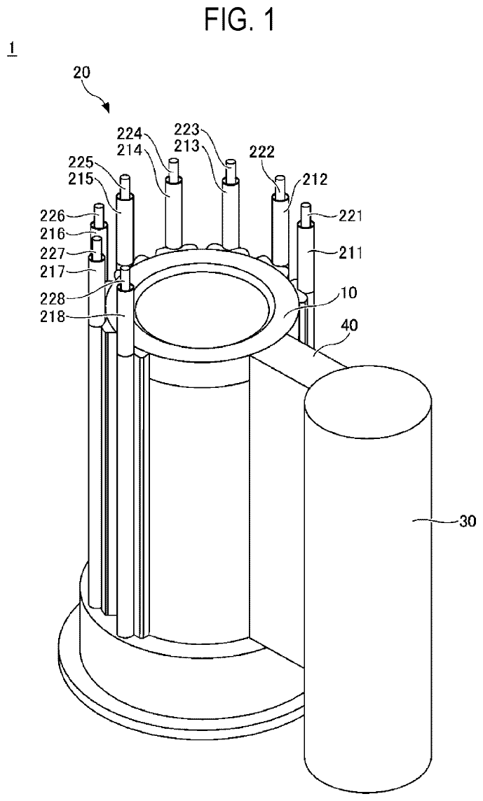

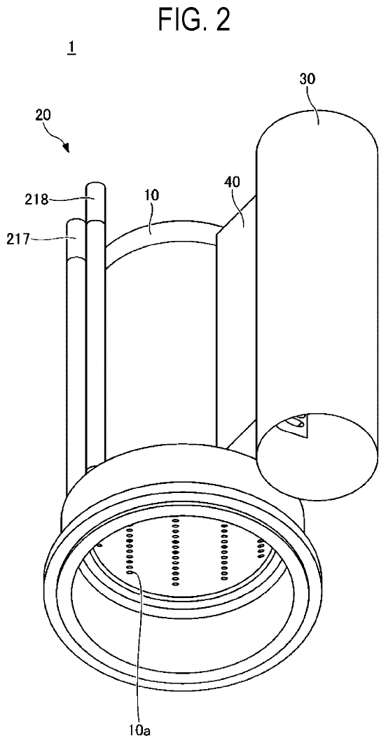

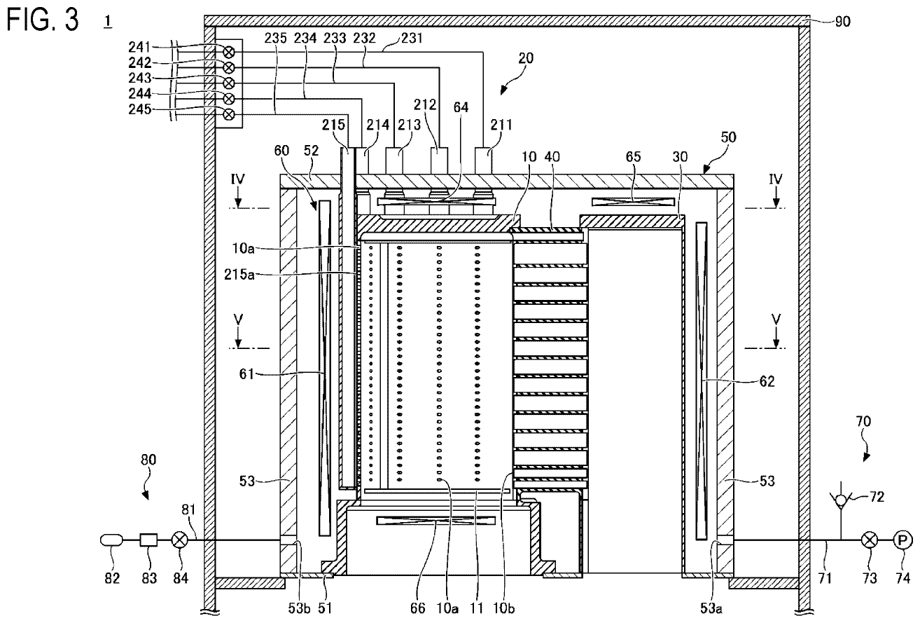

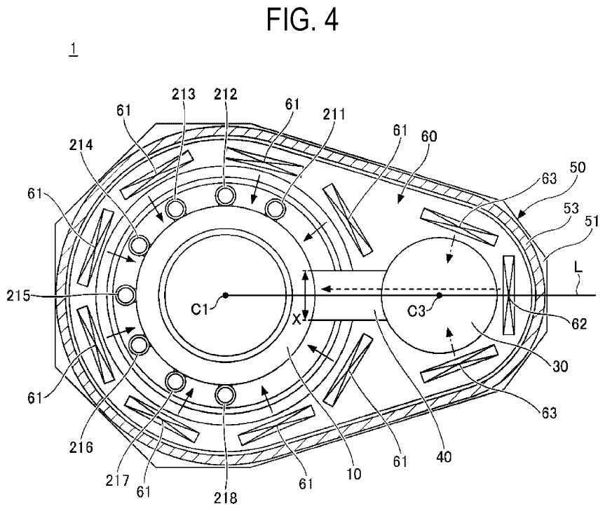

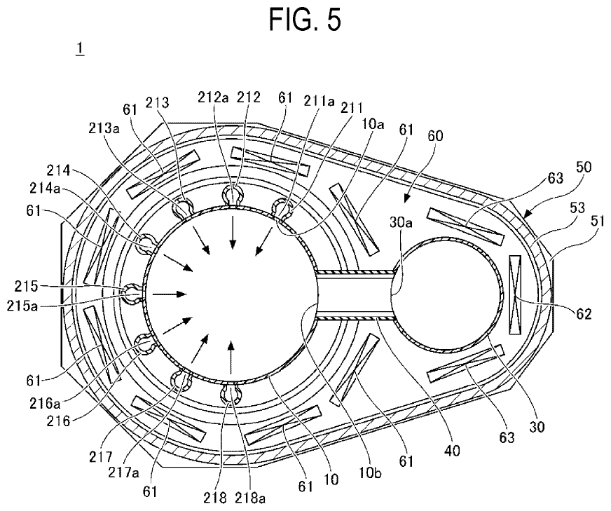

A substrate processing apparatus 1 according to an embodiment is described with reference to FIGS. 1 to 5. FIG. 1 is a perspective view showing the substrate processing apparatus 1 according to the embodiment when the substrate processing apparatus 1 is viewed obliquely from above. FIG. 2 is a perspective view showing the substrate processing apparatus 1 according to the embodiment when the substrate processing apparatus 1 is viewed obliquely from below. FIG. 3 is a vertical cross-sectional view showing the substrate processing apparatus 1 according to the embodiment. FIG. 4 is a horizontal cross-sectional view showing the substrate processing apparatus 1 according to the embodiment, taken along line IV-IV in FIG. 3 in an arrow direction. FIG. 5 is a horizontal cross-sectional view showing the substrate processing apparatus 1 according to the embodiment, taken along line V-V in FIG. 3 in an arrow direction.

The substrate processing apparatus 1 is a batch-type apparatus that collectively performs various processes on a plurality of substrates. The various processes include, for example, a film formation process for forming films on the substrates by atomic layer deposition (ALD) or chemical vapor deposition (CVD). The various processes may include an etching process for removing the films formed on the substrates.

The substrate processing apparatus 1 includes a reaction tube 10, a gas introducer 20, a vacuum pipe 30, an exhaust duct 40, a housing 50, a heating portion 60, a depressurizer 70, a pressurizer 80, and an apparatus housing 90. In FIGS. 1 and 2, the housing 50, the heating portion 60, the depressurizer 70, the pressurizer 80, and the apparatus housing 90 are not illustrated. The reaction tube 10, the gas introducer 20, and the exhaust duct 40 are joined together by, for example, welding, and are integrally formed. The reaction tube 10, the vacuum pipe 30, and the exhaust duct 40 are formed of, for example, quartz.

The reaction tube 10 has a cylindrical shape with an open lower end and a ceiling. An introduction opening 10a and an exhaust opening 10b are provided on an outer wall of the reaction tube 10.

The introduction opening 10a penetrates the outer wall of the reaction tube 10. The introduction opening 10a is provided at positions at which gas introduction ducts 211 to 218, which will be described later, are installed in a circumferential direction of the reaction tube 10. A plurality of introduction openings 10a is provided in a vertical direction from near an upper end to near a lower end of the reaction tube 10 at each position in the circumferential direction of the reaction tube 10. In this case, it is easy to uniformly supply gas to a range from the upper end to the lower end of the reaction tube 10.

The exhaust opening 10b penetrates the outer wall of the reaction tube 10. The exhaust opening 10b is provided at a position different from the introduction opening 10a in the circumferential direction of the reaction tube 10. The exhaust opening 10b is provided at a position at which the exhaust duct 40 is installed in the circumferential direction of the reaction tube 10. The exhaust opening 10b is a rectangular opening that extends in the vertical direction from near the upper end to near the lower end of the reaction tube 10. In this case, it is easy to uniformly exhaust gas over a range from the upper end to the lower end of the reaction tube 10.

A lower end opening of the reaction tube 10 is hermetically sealed by a cover (not shown). The cover is formed of, for example, metal such as stainless steel. A substrate holder 11 (FIG. 3) is accommodated inside the reaction tube 10. The substrate holder 11 holds a plurality of substrates in a horizontal posture arranged in multiple stages in the vertical direction. The number of substrates is not limited, but is, for example, between 25 and 200. The substrate holder 11 is formed of, for example, quartz.

The gas introducer 20 includes gas introduction ducts 211 to 218, nozzles 221 to 228, gas introduction pipes 231 to 238, and opening/closing valves 241 to 248. In FIG. 3, the gas introduction pipes 231 to 235 and the opening/closing valves 241 to 245 are shown.

The gas introduction ducts 211 to 218 are provided in the circumferential direction of the reaction tube 10. The gas introduction ducts 211 to 218 are provided to be spaced apart from each other in the circumferential direction of the reaction tube 10. In this case, the adjacent gas introduction ducts 211 to 218 can have a reduced thermal effect on each other. This can suppress a temperature drop within the gas introduction ducts 211 to 218 and suppress the generation of particles. The gas introduction ducts 211 to 218 are radially provided to be spaced apart from each other in the circumferential direction of the reaction tube 10. In this case, as indicated by arrows in FIG. 5, gases such as a raw material gas, a reaction gas, an etching gas, and a purge gas can be supplied to the inside of the reaction tube 10 from a plurality of positions (in multiple directions) in the circumferential direction of the reaction tube 10. Thus, an in-plane shape of a film formation or etching process can be easily adjusted. For example, a retention time of gas supplied to the surfaces of the substrates or a gas concentration distribution can be adjusted by adjusting a gas supply position or the amount of gas supplied. Therefore, it is easy to control the in-plane shape of the film formation or etching process compared to a unidirectional gas flow. The gas introduction ducts 211 to 218 are provided in this order counterclockwise from the exhaust opening 10b.

The gas introduction ducts 211 to 218 are installed on the outer wall of the reaction tube 10. In this case, a distance from the gas introduction ducts 211 to 218 to the substrates is shortened. Therefore, unnecessary thermal decomposition of the gas can be suppressed. In addition, when the gas introduction ducts 211 to 218 are installed on the outer wall of the reaction tube 10, there is no need to dispose the nozzles 221 to 228 inside the reaction tube 10. For this reason, a space between outer edges of the substrates and an inner wall of the reaction tube 10 can be narrowed, thereby reducing a gas flow in that space. As a result, the efficiency of gas supply between the vertically adjacent substrates is improved. Additionally, when the gas introduction ducts 211 to 218 are installed on the outer wall of the reaction tube 10, there is no need to form a nozzle chamber for accommodating the nozzles 221 to 228 by protruding a side wall of the reaction tube 10 radially outward. The gas introduction ducts 211 to 218 are integrally formed with, for example, the reaction tube 10. The gas introduction ducts 211 to 218 are formed of, for example, quartz.

The gas introduction ducts 211 to 218 have a tubular shape with closed lower ends and open upper ends. The upper ends of the gas introduction ducts 211 to 218 extend upward from an upper surface of the reaction tube 10 and penetrate the housing 50. In this case, an upper space of the housing 50 can be used as a space for installing the gas introduction pipes 231 to 238 or the opening/closing valves 241 to 248. Therefore, a pipe distance from the opening/closing valves 241 to 248 to the reaction tube 10 can be shortened. Further, the shape of the gas introduction pipes 231 to 238 can be simplified. Gas holes 211a to 218a (FIG. 5) are provided at positions of the gas introduction ducts 211 to 218 facing the reaction tube 10.

Each of the gas holes 211a to 218a has a rectangular shape extending in the vertical direction from near the upper end to near the lower end of the reaction tube 10. Each of the gas holes 211a to 218a extends from above the uppermost introduction opening 10a to below the lowermost introduction opening 10a. Gas flowing inside the gas introduction ducts 211 to 218 is discharged into the reaction tube 10 from the gas holes 211a to 218a.

The gas introduction duct 211 is provided at an angle range less than 90° counterclockwise from the exhaust duct 40 in the circumferential direction of the reaction tube 10. The gas introduction duct 212 is provided at an angle of 90° counterclockwise from the exhaust duct 40 in the circumferential direction of the reaction tube 10. The gas introduction ducts 213 and 214 are provided at an angle range greater than 90° and less than 180° counterclockwise from the exhaust duct 40. The gas introduction duct 215 is provided at an angle of 180° counterclockwise from the exhaust duct 40 in the circumferential direction of the reaction tube 10. In other words, the gas introduction duct 215 is provided at a position opposite to the exhaust duct 40. The gas introduction ducts 216 and 217 are provided at an angle range greater than 180° and less than 270° counterclockwise from the exhaust duct 40. The gas introduction duct 218 is provided at an angle of 270° counterclockwise from the exhaust duct 40 in the circumferential direction of the reaction tube 10. In other words, the gas introduction duct 218 is provided at a position opposite to the gas introduction duct 212.

The nozzles 221 to 228 are detachably inserted into the interior of the gas introduction ducts 211 to 218, respectively. In this case, the shape of the nozzles 221 to 228 can be changed according to the type of process, so that the optimal nozzles 221 to 228 can be used according to the type of process. An inner surface of each of the gas introduction ducts 211 to 218 has a shape that follows an outer surface of each of the nozzles 221 to 228, and a gap is provided between the inner surface of each of the gas introduction ducts 211 to 218 and the outer surface of each of the nozzles 221 to 228. This allows the volume of a space between the gas introduction ducts 211 to 218 and the nozzles 221 to 228 to be reduced. Therefore, the retention of gas in this space is suppressed, thereby improving the efficiency of gas supply to the substrates. In addition, since a surface area in contact with gas is reduced, the generation of particles in this space can be suppressed. Thus, cleaning this space is easy. In a cross-section perpendicular to a longitudinal direction of the nozzles 221 to 228, the inner surface of the gas introduction ducts 211 to 218 is, for example, circular, and the outer surface of the nozzles 221 to 228 is, for example, circular. In the cross-section perpendicular to the longitudinal direction of the nozzles 221 to 228, the inner surface of the gas introduction ducts 211 to 218 may be elliptical, and the outer surface of the nozzles 221 to 228 may also be elliptical.

The nozzles 221 to 228 are provided with gas discharge holes (not shown). The gas discharge holes are provided, for example, in portions of tube walls of the nozzles 221 to 228 inserted into the gas introduction ducts 211 to 218. The upper ends of the nozzles 221 to 228 are connected to gas sources (not shown) via the gas introduction pipes 231 to 238, respectively. Gases from the gas sources are introduced into the nozzles 221 to 228 from the upper ends of the nozzles 221 to 228 and discharged into the reaction tube 10 through the gas discharge holes, the gas holes 211a to 218a, and the introduction openings 10a. The nozzles 221 to 228 are not illustrated in FIGS. 2 to 5.

The nozzles 221 to 228 may not be provided. In this case, the upper ends of the gas introduction ducts 211 to 218 are connected to the gas sources via the gas introduction pipes 231 to 238, respectively. Gases from the gas sources are introduced into the gas introduction ducts 211 to 218 from the upper ends of the gas introduction ducts 211 to 218 and discharged into the reaction tube 10 through the gas holes 211a to 218a. For example, when gases that are easily thermally decomposed, such as hexachlorodisilane (HCD) gas and dichlorosilane (DCS) gas, are used, the nozzles 221 to 228 may not be necessary.

The gas introduction pipes 231 to 238 are provided in an upper space of the housing 50. One end of each of the gas introduction pipes 231 to 238 is connected to each of the corresponding gas introduction ducts 211 to 218 or the corresponding nozzles 221 to 228, and the other end thereof extends through the apparatus housing 90 to the exterior of the apparatus housing 90. The gas introduction pipes 231 to 238 are provided with the opening/closing valves 241 to 248. The gas introduction pipes 231 to 238 may also be provided with flow rate controllers such as mass flow controllers.

The opening/closing valves 241 to 248 are provided in the upper space of the housing 50. The opening/closing valves 241 to 248 are provided in the middle of the corresponding gas introduction pipes 231 to 238. The opening/closing valves 241 to 248 are installed, for example, on an inner wall of the apparatus housing 90. The opening/closing valves 241 to 248 are valves that switch a gas flow on and off.

The vacuum pipe 30 has a cylindrical shape with an open lower end and a ceiling. The vacuum pipe 30 is provided to be spaced apart from the reaction tube 10. An opening 30a (FIG. 5) is provided on an outer wall of the vacuum pipe 30 at the same position as the exhaust duct 40 in a circumferential direction of the vacuum pipe 30. The opening 30a is a rectangular opening extending in the vertical direction from near an upper end to near a lower end of the vacuum pipe 30. A vertical length of the opening 30a may be the same as a vertical length of the exhaust opening 10b. The axis of the vacuum pipe 30 may be parallel to the axis of the reaction tube 10. The lower end of the vacuum pipe 30 is connected to an exhaust device (not shown) such as a vacuum pump via a pipe (not shown). A cross-sectional area of a flow path of the vacuum pipe 30 may be equal to or greater than a cross-sectional area of a flow path of the exhaust duct 40. In this case, exhaust flow velocity in the vertical direction becomes uniform, so that a uniform laminar flow in the vertical direction is formed. Thereby, inter-plane uniformity of the film formation or etching process is improved.

The exhaust duct 40 connects the reaction tube 10 and the vacuum pipe 30. The exhaust duct 40 allows communication between the interior of the reaction tube 10 and the interior of the vacuum pipe 30. One end of the exhaust duct 40 is connected to the outer wall of the reaction tube 10 to cover the exhaust opening 10b, and the other end thereof is connected to the outer wall of the vacuum pipe 30 to cover the opening 30a. In this case, compared to directly connecting the vacuum pipe 30 to the reaction tube 10 without providing the exhaust duct 40, a length X (FIG. 4) occupied by the exhaust duct 40 in the circumferential direction of the reaction tube 10 can be shortened. As a result, an installable length of the gas introduction ducts 211 to 218 in the circumferential direction of the reaction tube 10 increases. Thus, the number of the gas introduction ducts 211 to 218 provided on the outer wall of the reaction tube 10 can be increased. The exhaust duct 40 may be divided into a plurality of parts in the vertical direction. In this case, a gas flow from the interior of the reaction tube 10 towards the vacuum pipe 30 is rectified. For this reason, the uniformity of the gas flow at different positions in the vertical direction inside the reaction tube 10 is improved.

The housing 50 accommodates the reaction tube 10, the gas introducer 20, the vacuum pipe 30, the exhaust duct 40, and the heating portion 60 therein. Since the housing 50 accommodates the heating portion 60 including heaters, the housing 50 is also called a heater shell. The housing 50 includes a bottom portion 51, a ceiling portion 52, and a side portion 53.

The bottom portion 51 supports the reaction tube 10 and the vacuum pipe 30. The ceiling portion 52 is provided above the upper surface of the reaction tube 10 and the upper surface of the vacuum pipe 30. The ceiling portion 52 covers the upper surface of the reaction tube 10 and the upper surface of the vacuum pipe 30. The side portion 53 is provided around the reaction tube 10, the gas introducer 20, the vacuum pipe 30, and the exhaust duct 40. The side portion 53 covers the reaction tube 10, the gas introducer 20, the vacuum pipe 30, and the exhaust duct 40. A lower end of the side portion 53 is connected to the bottom portion 51, and an upper end thereof is connected to the ceiling portion 52. The bottom portion 51, the ceiling portion 52, and the side portion 53 are configured, for example, separately. The bottom portion 51, the ceiling portion 52, and the side portion 53 may be integrally formed.

The heating portion 60 is provided inside the housing 50. The heating portion 60 includes a first side heater 61, a second side heater 62, a third side heater 63, a first ceiling heater 64, a second ceiling heater 65, and a lower heater 66. The first side heater 61, the second side heater 62, the third side heater 63, the first ceiling heaters 64, the second ceiling heaters 65, and the lower heater 66 are, for example, carbon wire heaters. In this case, the substrates accommodated inside the reaction tube 10 can be rapidly heated and cooled.

A plurality of first side heaters 61 is provided around the reaction tube 10. The plurality of first side heaters 61 is radially provided at intervals in the circumferential direction of the reaction tube 10. Each of the first side heaters 61 is positioned at a different location from the exhaust duct 40 in the circumferential direction of the reaction tube 10. Each of the first side heaters 61 may be divided into a plurality of parts in the vertical direction. In this case, temperature in the vertical direction can be independently adjusted by independently controlling the first side heaters 61 divided into the plurality of parts. As indicated by solid arrows in FIG. 4, the first side heaters 61 heat the substrates accommodated inside the reaction tube 10 from the exterior of the reaction tube 10 through thermal radiation.

The second side heater 62 is provided in a different position from the first side heater 61 in the circumferential direction of the reaction tube 10. The second side heater 62 is provided at a different position from the plurality of gas introduction ducts 211 to 218 in the circumferential direction of the reaction tube 10. The second side heater 62 is provided to include the same position as the exhaust duct 40 in the circumferential direction of the reaction tube 10. Since the exhaust duct 40 is provided around the reaction tube 10 at the same position as the exhaust duct 40 in the circumferential direction of the reaction tube 10, the second side heater 62 cannot be disposed around the reaction tube 10. Therefore, the second side heater 62 is provided around the vacuum pipe 30. In other words, the second side heater 62 is provided at a position to which a distance from a center C1 of the reaction tube 10 is farther than a distance from the center C1 to the first side heater 61. For example, the second side heater 62, when viewed in a plane, is provided to include a virtual half straight line L extending through a center C3 of the vacuum pipe 30 starting from the center C1 of the reaction tube 10. The second side heater 62 may be divided into a plurality of parts in the vertical direction. In this case, temperature in the vertical direction can be independently adjusted by independently controlling the second side heater 62 divided into the plurality of parts. As indicated by a broken line arrow in FIG. 4, the second side heater 62 heats the vacuum pipe 30 and the exhaust duct 40 through thermal radiation and also heats the substrates accommodated inside the reaction tube 10. Thus, the substrates accommodated inside the reaction tube 10 is heated from all directions around the reaction tube 10 by the first side heater 61 and the second side heater 62. Therefore, the in-plane temperature uniformity of a substrate is improved.

A plurality of third side heaters 63 is provided around the vacuum pipe 30. The plurality of third side heaters 63 is provided at intervals in the circumferential direction of the vacuum pipe 30. Each third side heater 63 is positioned at a position different from the second side heater 62 in the circumferential direction of the vacuum pipe 30. Each third side heater 63, when viewed in a plane, is provided without including the virtual half straight line L. Each third side heater 63 may be divided into a plurality of parts in the vertical direction. In this case, temperature in the vertical direction can be independently adjusted by independently controlling the third side heater 63 divided into the plurality of parts. As indicated by dash-dotted line arrows in FIG. 4, the third side heaters 63 heat the vacuum pipe 30.

The first ceiling heater 64 is provided between the upper surface of the reaction tube 10 and the ceiling portion 52 of the housing 50. The first ceiling heater 64 heats the substrates accommodated inside the reaction tube 10 from above the reaction tube 10 through thermal radiation. The number of first ceiling heaters 64 may be one or may be two or more.

The second ceiling heater 65 is provided between the upper surface of the vacuum pipe 30 and the ceiling portion 52 of the housing 50. The second ceiling heater 65 heats the vacuum pipe 30 from above the vacuum pipe 30 through thermal radiation. The number of second ceiling heaters 65 may be one or may be two or more.

A plurality of lower heaters 66 is provided around the lower portion of the reaction tube 10. The plurality of the lower heaters 66 is provided radially at intervals in the circumferential direction of the reaction tube 10. The lower heaters 66 are positioned below the substrate holder 11. The lower heaters 66 heat the lower portion of the reaction tube 10 through thermal radiation and suppress heat dissipation from the lower end opening of the reaction tube 10.

The depressurizer 70 reduces pressure inside the housing 50. The depressurizer 70 includes a pipe 71, a safety valve 72, an opening/closing valve 73, and a vacuum pump 74.

The pipe 71 is connected to a port 53a provided in the side portion 53 of the housing 50. The pipe 71 extends through the side portion 53 and the apparatus housing 90 to the exterior of the apparatus housing 90. In the pipe 71, the safety valve 72, the opening/closing valve 73, and the vacuum pump 74 are provided in order from the housing 50 side. The safety valve 72, the opening/closing valve 73, and the vacuum pump 74 are provided, for example, outside the apparatus housing 90. The safety valve 72, the opening/closing valve 73, and the vacuum pump 74 may be provided outside the housing 50 but inside the apparatus housing 90.

The safety valve 72 is changed to an open state from a closed state when pressure inside the housing 50 exceeds a set pressure, thereby maintaining the internal pressure of the housing 50 below the set pressure.

The opening/closing valve 73 is a valve that switches a gas flow on and off.

The vacuum pump 74 reduces pressure inside the housing 50 through the pipe 71.

When the opening/closing valve 73 is changed to an open state, the interior of the housing 50 is depressurized by the vacuum pump 74. When the interior of the housing 50 is depressurized, heat transfer by convection is suppressed. This suppresses heat transfer to the exterior of the housing 50, so that a space above the housing 50 can be used to install the opening/closing valves 241 to 248. In addition, since a thermal insulation material becomes unnecessary, a distance between the reaction tube 10 and the housing 50 can be shortened. Thus, a distance from the opening/closing valves 241 to 248 to the substrates can be shortened and thus gas controllability is improved. Furthermore, when the side heaters (the first side heater 61, the second side heater 62, and the third side heater 63) are divided into a plurality of parts in the vertical direction, convection does not influence the interior of the housing 50, so that heaters have little influence on one another in the vertical direction. Therefore, inter-plane (vertical direction) temperature controllability is improved. This makes it easy to selectively heat only the lower portion of the reaction tube 10, selectively heat only the center of the reaction tube 10, or selectively heat only the upper portion of the reaction tube 10.

The pressurizer 80 restores the internal pressure of the depressurized housing 50 to atmospheric pressure. The pressurizer 80 includes a pipe 81, a gas source 82, a flow rate controller 83, and an opening/closing valve 84.

The pipe 81 is connected to a port 53b provided in the side portion 53 of the housing 50. In the pipe 81, the gas source 82, the flow rate controller 83, and the opening/closing valve 84 are provided in order from an upstream side to a downstream side of a gas flow direction. The gas source 82, the flow rate controller 83, and the opening/closing valve 84 are provided, for example, outside the apparatus housing 90. The gas source 82, the flow rate controller 83, and the opening/closing valve 84 may be provided outside the housing 50 but inside the apparatus housing 90.

The gas source 82 is, for example, a supply source of an inert gas. The inert gas is, for example, nitrogen gas. The inert gas may be argon gas.

The flow rate controller 83 controls the flow rate of gas flowing through the pipe 81. The flow rate controller 83 is, for example, a mass flow controller.

The opening/closing valve 84 is a valve that switches a gas flow on and off.

When the opening/closing valve 84 is changed to an open state, the flow rate of gas from the gas source 82 is controlled by the flow rate controller 83, and the gas with the controlled flow rate is supplied to the interior of the housing 50. Thus, the internal pressure of the depressurized housing 50 is restored to atmospheric pressure.

The apparatus housing 90 surrounds the housing 50. The apparatus housing 90 covers the entirety of the housing 50. The apparatus housing 90 supports the bottom portion 51 of the housing 50.

As described above, according to the substrate processing apparatus 1 of the embodiment, the reaction tube 10, the gas introducer 20, the vacuum pipe 30, and the exhaust duct 40 are accommodated inside the housing 50, and the heating portion 60 is provided inside the housing 50. This allows the substrates accommodated inside the reaction tube 10 to be heated from all directions around the reaction tube 10. Thus, the in-plane temperature uniformity of a substrate can be improved. As a result, processing uniformity of the substrate is raised.

### Pipe Connection Structure

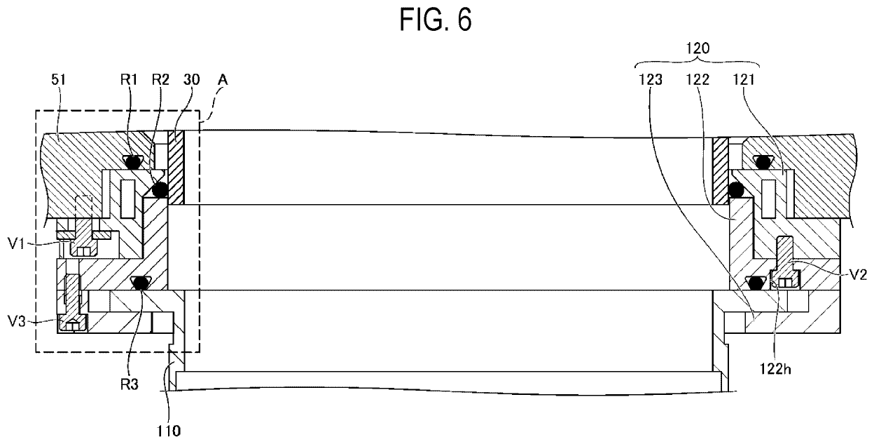

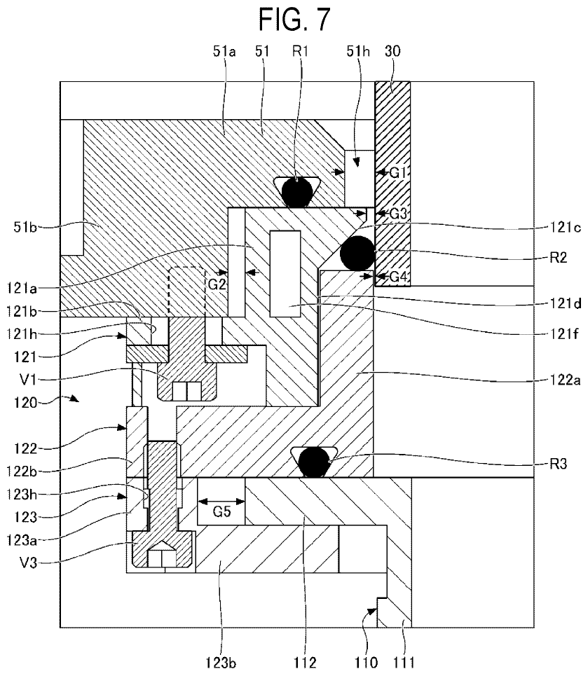

A pipe connection structure in which the vacuum pipe 30 and an exhaust pipe 110 are connected with each other will now be described with reference to FIGS. 6 and 7. FIG. 6 is a cross-sectional view showing the pipe connection structure. FIG. 7 is an enlarged view of area A in FIG. 6.

The pipe connection structure is provided through the bottom portion 51 of the housing 50. The bottom portion 51 has an opening 51h at a position through which a lower end of the vacuum pipe 30 is inserted. The opening 51h includes a first opening and a second opening. The first opening is provided at an upper portion of the opening 51h and has a first opening diameter. The second opening is provided at a lower portion of the opening 51h and has a second opening diameter larger than the first opening diameter. The bottom portion 51 includes a small-diameter portion 51a forming the first opening and a large-diameter portion 51b forming the second opening. The pipe connection structure includes the vacuum pipe 30, the exhaust pipe 110, and a fixing member 120.

The vacuum pipe 30 is provided inside the housing 50. The lower end of the vacuum pipe 30 is inserted through the opening 51h. Since an opening diameter of the opening 51h is larger than an outer diameter of the vacuum pipe 30, a gap G1 is formed between the opening 51h and the vacuum pipe 30. In this case, since the bottom portion 51 and the vacuum pipe 30 are separated by the gap G1, damage to the vacuum pipe 30 can be prevented.

The exhaust pipe 110 is formed of, for example, a nickel alloy. The exhaust pipe 110 is provided below the bottom portion 51. The exhaust pipe 110 is provided directly below the vacuum pipe 30. The exhaust pipe 110 is provided coaxially or approximately coaxially with the vacuum pipe 30. The interior of the exhaust pipe 110 is in communication with the interior of the vacuum pipe 30. The exhaust pipe 110 includes a pipe portion 111 and a pipe flange portion 112. The pipe flange portion 112 is provided at an upper portion of the pipe portion 111. The pipe flange portion 112 protrudes radially outward from an outer side surface of the pipe portion 111. The pipe flange portion 112 has, for example, an annular plate shape. An end of the pipe portion 111 that is not provided with the pipe flange portion 112 is connected to a vacuum pump (not shown). The vacuum pump exhausts gas introduced into the reaction tube 10 through the exhaust pipe 110, the vacuum pipe 30, and the exhaust duct 40.

The fixing member 120 fixes the exhaust pipe 110 to the bottom portion 51. The fixing member 120 includes a first flange 121, a second flange 122, and a clamp 123.

The first flange 121 is formed of, for example, stainless steel. The first flange 121 includes a pipe portion 121a and a flange portion 121b. The first flange 121 is fixed to the bottom portion 51 by a screw V1 inserted through the flange portion 121b in a state in which the pipe portion 121a is fitted into an inner side of the large-diameter portion 51b.

An outer diameter of the pipe portion 121a is larger than an opening diameter of the small-diameter portion 51a. An upper surface of the pipe portion 121a contacts a lower surface of the small-diameter portion 51a. An O-ring R1, which is a sealing member, is provided at a contact portion between the upper surface of the pipe portion 121a and the lower surface of the small-diameter portion 51a. The O-ring R1 contacts the upper surface of the pipe portion 121a and the lower surface of the small-diameter portion 51a to seal a gap between the upper surface of the pipe portion 121a and the lower surface of the small-diameter portion 51a. The O-ring R1 hermetically separates the interior of the housing 50 and the exterior of the housing 50.

The outer diameter of the pipe portion 121a is smaller than the opening diameter of the large-diameter portion 51b. A gap G2 is provided between an outer side surface of the pipe portion 121a and an inner side surface of the large-diameter portion 51b. In this case, even if a central axis of the vacuum pipe 30 is misaligned with a central axis of the opening 51h due to tolerances or manufacturing errors of quartz, misalignment therebetween can be absorbed by the gap G2.

The pipe portion 121a has an inner inclined surface 121c, an inner diameter of which widens from top to bottom. The pipe portion 121a has an inner side surface 121d, the inner diameter of which is constant from top to bottom. The inner side surface 121d is positioned below the inner inclined surface 121c. A boundary between the inner inclined surface 121c and the inner side surface 121d is located above the lower end of the vacuum pipe 30.

An inner diameter of the pipe portion 121a at the upper end thereof is larger than an outer diameter of the vacuum pipe 30. A gap G3 is provided between an inner side surface of the pipe portion 121a at the upper end thereof and an outer side surface of the vacuum pipe 30. Since the first flange 121 and the vacuum pipe 30 are separated by the gap G3, damage to the vacuum pipe 30 can be prevented.

The flange portion 121b is provided at a lower portion of the pipe portion 121a. The flange portion 121b protrudes radially outward from the outer side surface of the pipe portion 121a. The flange portion 121b has, for example, an annular plate shape. The flange portion 121b is provided with an insertion through-hole 121h through which the screw V1 is inserted. A plurality of insertion through-holes 121h is provided at intervals in the circumferential direction of the flange portion 121b. The first flange 121 is fixed to the bottom portion 51 by the screw V1 inserted through the insertion through-hole 121h.

The first flange 121 is provided with a refrigerant flow path 121f for circulating a

refrigerant. By circulating the refrigerant through the refrigerant flow path 121f, the O-ring R1 can be cooled via the first flange 121. Thereby, even if the bottom portion 51 is heated due to thermal radiation, the O-ring R1 contacting the bottom portion 51 is prevented from reaching a high temperature.

The second flange 122 is formed of, for example, a nickel alloy. The second flange 122 includes a pipe portion 122a and a flange portion 122b. The second flange 122 is fixed to the first flange 121 by a screw V2 inserted through the flange portion 122b in a state in which the pipe portion 122a is fitted into an inner side of the pipe portion 121a.

An upper end of the pipe portion 122a is positioned above the lower end of the vacuum pipe 30. The upper end of the pipe portion 122a is positioned approximately at the same height as the boundary between the inner inclined surface 121c and the inner side surface 121d.

An outer diameter of the pipe portion 122a is slightly smaller than an inner diameter of the inner side surface 121d of the pipe portion 121a. An outer side surface of the pipe portion 122a has a curved shape along the inner side surface 121d of the pipe portion 121a. In this case, the second flange 122 can be easily fitted into the first flange 121.

An inner diameter of the pipe portion 122a is constant in the vertical direction. The inner diameter of the pipe portion 122a is larger than the outer diameter of the vacuum pipe 30. A gap G4 is provided between an inner side surface of the pipe portion 122a and the outer side surface of the vacuum pipe 30. In this case, since the pipe portion 122a and the vacuum pipe 30 are separated by the gap G4, damage to the vacuum pipe 30 can be prevented.

An O-ring R2, which is a sealing member, is provided in an area surrounded by the outer side surface of the vacuum pipe 30, the inner inclined surface 121c of the first flange 121, and the upper end of the second flange 122. The O-ring R2 contacts the outer side surface of the vacuum pipe 30, the inner inclined surface 121c of the first flange 121, and the upper end of the second flange 122, thereby sealing the gaps G3 and G4. The O-ring R2 hermetically separates the interior of the vacuum pipe 30, the interior of the housing 50, and the exterior of the housing 50 from each other. The inner diameter of the pipe portion 122a may be dimensioned such that the O-ring R2 does not protrude from the gap G4 under vacuuming.

The flange portion 122b is provided at a lower portion of the pipe portion 122a. The flange portion 122b protrudes radially outward from the outer side surface of the pipe portion 122a. The flange portion 122b has, for example, an annular plate shape. The outer diameter of the flange portion 122b is the same as, for example, the outer diameter of the flange portion 121b. An upper surface of the flange portion 122b contacts a lower surface of the flange portion 121b. The flange portion 122b is provided with an insertion through-hole 122h through which the screw V2 is inserted. A plurality of insertion through-holes 122h is provided at intervals in the circumferential direction of the flange portion 122b. The second flange 122 is fixed to the first flange 121 by the screws V2 inserted through the insertion through-holes 122h.

The clamp 123 is formed of, for example, stainless steel. The clamp 123 includes a pipe portion 123a and a pressing portion 123b. The clamp 123 is fixed to the flange portion 122b by a screw V3 by inserting the pipe flange portion 112 between the clamp 123 and the lower surface of the flange portion 122b by the pressing portion 123b.

An outer diameter of the pipe portion 123a is the same as, for example, an outer diameter of the flange portion 122b. An inner diameter of the pipe portion 123a is larger than an outer diameter of the pipe flange portion 112. A gap G5 is provided between an inner side surface of the pipe portion 123a and an outer side surface of the pipe flange portion 112. In this case, even if the central axis of the vacuum pipe 30 is misaligned with the central axis of the exhaust pipe 110, misalignment therebetween can be absorbed by the gap G5. Therefore, the exhaust pipe 110 can be easily installed while ensuring airtightness. The pipe portion 123a is provided with an insertion through-hole 123h through which the screw V3 is inserted. A plurality of insertion through-holes 123h is provided at intervals in the circumferential direction of the pipe portion 123a. The clamp 123 is fixed to the second flange 122 by the screw V3 inserted through the insertion through-hole 123h.

The pressing portion 123b is provided at the lower portion of the pipe portion 123a. The pressing portion 123b protrudes radially inward from the inner side surface of the pipe portion 123a. The pressing portion 123b has, for example, an annular plate shape. An inner diameter of the pressing portion 123b is larger than an outer shape of the pipe portion 111 of the exhaust pipe 110.

An O-ring R3, which is a sealing member, is provided at a contact portion at which the lower surface of the flange portion 122b contacts the upper surface of the pipe flange portion 112. The O-ring R3 contacts the lower surface of the flange portion 122b and the upper surface of the pipe flange portion 112, thereby sealing a gap between the lower surface of the flange portion 122b and the upper surface of the pipe flange portion 112. The O-ring R3 hermetically separates the interior of the vacuum pipe 30 from the exterior of the housing 50.

### Pipe Connection Method

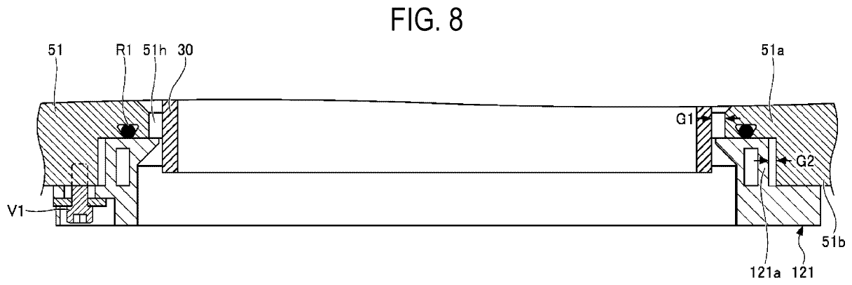

A pipe connection method for connecting the vacuum pipe 30 and the exhaust pipe 110 will now be described with reference to FIGS. 8 to 10. FIGS. 8 to 10 are cross-sectional views showing the pipe connection method.

First, the lower end of the reaction tube 10 is fixed to the bottom portion 51 (FIG. 3). As a result, as shown in FIG. 8, the lower end of the vacuum pipe 30, which is integrally formed with the reaction tube 10, is inserted into the opening 51h. In this case, since, the opening diameter of the opening 51h is larger than the outer diameter of the vacuum pipe 30, the gap G1 is formed between the opening 51h and the vacuum pipe 30. In this case, since the bottom portion 51 and the vacuum pipe 30 are separated by the gap G1, damage to the vacuum pipe 30 can be prevented.

Next, as shown in FIG. 8, the O-ring R1 is installed on the lower surface of the small-diameter portion 51a, the first flange 121 is installed at the lower end of the vacuum pipe 30, and the first flange 121 is fixed to the bottom portion 51 by the screw V1. In this case, since the outer diameter of the pipe portion 121a is smaller than the opening diameter of the large-diameter portion 51b, the gap G2 is formed between the outer side surface of the pipe portion 121a and the inner side surface of the large-diameter portion 51b. In this case, even if the central axis of the vacuum pipe 30 is misaligned with the central axis of the opening 51h due to tolerances or manufacturing errors of quartz, misalignment therebetween can be absorbed by the gap G2.

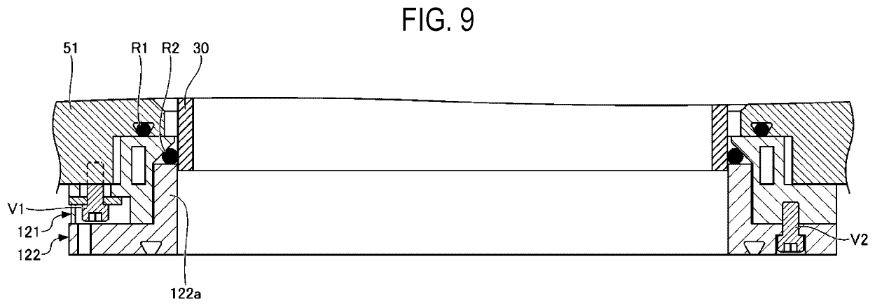

Next, as shown in FIG. 9, the O-ring R2 is installed between the outer side surface of the vacuum pipe 30 and an inner side surface of the first flange 121. Then, the second flange 122 is fixed to the first flange 121 by the screw V2 by fitting the pipe portion 122a of the second flange 122 into an inner side of the first flange 121. Since the outer side surface of the pipe portion 122a has a curved shape along the inner side surface 121d of the pipe portion 121a, the second flange 122 can be easily fitted into the first flange 121.

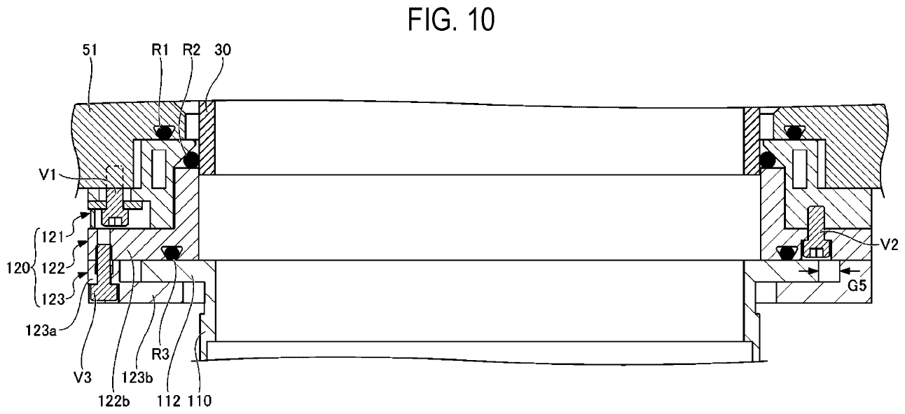

Next, as shown in FIG. 10, the pipe flange portion 112 of the exhaust pipe 110 is brought into contact with the lower surface of the second flange 122 through the O-ring R3. Then, the pipe flange portion 112 is inserted between and the clamp 123 and the lower surface of the flange portion 122b by the pressing portion 123b of the clamp 123, and the clamp 123 is fixed to the second flange 122 by the screw V3. In this case, since the inner diameter of the pipe portion 123a is larger than the outer diameter of the pipe flange portion 112, the gap G5 is formed between the inner side surface of the pipe portion 123a and the outer side surface of the pipe flange portion 112. In this case, even if the central axis of the vacuum pipe 30 is misaligned with the central axis of the exhaust pipe 110, misalignment therebetween can be absorbed by the gap G5. Therefore, the exhaust pipe 110 can be easily installed while ensuring airtightness.

It should be noted that the embodiments disclosed herein are exemplary in all aspects and are not restrictive. The above-described embodiments may be omitted, replaced, or modified in various forms without departing from the scope and spirit of the appended claims.

According to the present disclosure in some embodiments, it is possible to easily install the reaction tube and the vacuum pipe that are integrally formed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a reaction tube;
a vacuum pipe integrally formed with the reaction tube;
a housing configured to accommodate the reaction tube and the vacuum pipe therein;
an exhaust pipe provided below the housing; and
a fixing member configured to fix the exhaust pipe to the housing,
wherein the housing has a bottom portion configured to support the reaction tube,
the bottom portion has an opening with an opening diameter larger than an outer diameter of the vacuum pipe,
the vacuum pipe has a lower end inserted through the opening, and
the exhaust pipe is fixed to the housing in a state in which an interior thereof communicates with an interior of the vacuum pipe.

2. The substrate processing apparatus of claim 1, wherein a pipe axis of the vacuum pipe is parallel to a pipe axis of the reaction tube.

3. The substrate processing apparatus of claim 1, wherein an upper portion of the exhaust pipe is provided with a flange portion protruding radially outward, and
wherein the fixing member includes:
a first flange disposed around a lower end of the vacuum pipe with a first gap and fixed to the bottom portion;
a second flange disposed on an inner side of the first flange and fixed to the first flange; and
a clamp fixed to the second flange by inserting the flange portion between the clamp and the second flange.

4. The substrate processing apparatus of claim 3, wherein the fixing member has a first sealing member that contacts the bottom portion and the first flange, and hermetically separates an interior of the housing and an exterior of the housing from each other.

5. The substrate processing apparatus of claim 3, wherein the fixing member has a second sealing member that contacts an outer side surface of the vacuum pipe, an inner side surface of the first flange, and an upper end of the second flange, and hermetically separates the interior of the vacuum pipe, an interior of the housing, and an exterior of the housing from each other.

6. The substrate processing apparatus of claim 3, wherein the fixing member has a third sealing member that contacts the second flange and the flange portion, and hermetically separates an exterior of the housing and the interior of the vacuum pipe from each other.

7. The substrate processing apparatus of claim 3, wherein a second gap is provided between an outer side surface of the first flange and an inner surface of the opening.

8. The substrate processing apparatus of claim 3, wherein a third gap is provided between an outer side surface of the flange portion and an inner side surface of the clamp.

9. The substrate processing apparatus of claim 3, wherein a refrigerant flow path is provided inside the first flange.

10. The substrate processing apparatus of claim 1, wherein the reaction tube and the vacuum pipe are formed of quartz.
